(19) United States
(12) Patent Application Publication
(10) Pub. No.: US 2008/0265416 A1
(43) Pub. Date: Oct. 30, 2008

(54) Metal line formation using advaced CMP slurry

(76) Inventors: Shen-Nan Lee, Jhudong Township (TW); Jin-Yiing Song, Hsin-Chu (TW); Syun-Ming Jang, Hsin-Chu (TW)

Correspondence Address: SLATER & MATSIL, L.L.P., 17950 PRESTON ROAD, SUITE 1000, DALLAS, TX, 75252, US

(21) Appl. No.: 11/796,206

(22) Filed: Apr. 27, 2007

(51) Int. Cl. H01L 23/52; H01L 21/3205

(52) U.S. Cl. 257/751; 438/645; 257/E23.141; 257/E21.294

(57) ABSTRACT

An integrated circuit and methods for forming the same are provided. The method includes providing a semiconductor substrate; forming a low-k dielectric layer over the semiconductor substrate; forming an opening extending from a top surface of the low-k dielectric layer into the low-k dielectric layer; forming a diffusion barrier layer in the opening, wherein the diffusion barrier layer has a top edge substantially level with a top surface of the low-k dielectric layer; filling a metal line in the opening; recessing a top surface of the metal line below a top edge of the diffusion barrier layer to form a recess; and forming a metal cap on the metal line, wherein the metal cap is substantially within the recess.

### TECHNICAL FIELD

This invention relates generally to metallization layers of integrated circuits, and more particularly to the formation of metal caps on metal lines.

### BACKGROUND

A conventional integrated circuit contains a plurality of metal lines separated by inter-wiring spacings, which metal lines include bus lines, bit lines, word lines, logic interconnect lines, and the like. Typically, the metal lines of vertically spaced metallization layers are electrically interconnected by vias. Metal lines formed in trench-like openings typically extend substantially parallel to the semiconductor substrate. Semiconductor devices of this type, according to current technology, may comprise eight or more levels of metallization layers to satisfy device geometry and micro miniaturization requirements.

A common method for forming metal lines is known as “damascene.” Generally, this method involves forming an opening in a dielectric layer, which separates the vertically spaced metallization layers. The opening is typically formed using conventional lithographic and etching techniques. After an opening is formed, the opening is filled with copper or copper alloys to form a metal line and/or a via. Excess copper or copper alloys on the surface of the dielectric layer are then removed by a chemical mechanical polish (CMP). Although copper has low resistivity and high reliability, copper still suffers from electro-migration (EM) and stress-migration (SM) reliability issues as geometries continue to shrink and current densities increase. Various approaches are thus explored to solve these problems.

FIG. 1 illustrates a conventional interconnect structure including damascene structures. Copper lines 2 and 4 are formed in a same metallization layer and are insulated from low-k dielectric layer 14 by diffusion barrier layers 6 and 8, respectively. Metal caps 10 and 12, which are typically formed of materials suffering less from electro-migration, are formed on top of copper lines 2 and 4, respectively. The formation of metal caps greatly improves the reliability of the integrated circuit by reducing the surface migration of the copper lines. It has been found that under stressed conditions, the mean-time-to-failure (MTTF) of the illustrated interconnect structure may be ten times longer than that of interconnect structures having no metal caps. The improvement is partially attributed to the reduction of electro-migration. With metal caps 10 and 12, stress-induced void formation is also significantly reduced.

Metal caps are typically formed using electroless plating, during which the semiconductor wafer is submerged into a metal-ion-containing solution. Metal ions in the solution are selectively deposited on copper lines 2 and 4, and thus metal caps 10 and 12 are selectively formed on the copper lines, but not on low-k dielectric layer 14. A problem of this method is the difficulty of controlling the thickness uniformity of metal caps 10 and 12. Conventional structures have shown that at the interfaces between metal caps 10 and 12 and respective barrier layers 6 and 8, metal caps 10 and 12 are typically thinner. Even worse, the caps 10 and 12 may not be able to cover the entire top surfaces of copper lines 2 and 4. Electro-migration through uncovered portions of copper lines 2 and 4 are significant, and hence reduce the lifetime of the interconnection structures.

Furthermore, in conventional processes for forming copper lines 10 and 12, chemical mechanical polish (CMP) is performed. Due to pattern-loading effects, a wider copper line 2 typically has a greater degree of dishing effect than a narrower copper line 4, resulting in increased topography. This results in the increased loading effect in the depth-of-focus (DOF) for the subsequent lithograph process. New methods for solving the above-discussed problems are thus needed.

### SUMMARY OF THE INVENTION

In accordance with one aspect of the present invention, a method of forming an integrated circuit includes providing a semiconductor substrate; forming a low-k dielectric layer over the semiconductor substrate; forming an opening extending from a top surface of the low-k dielectric layer into the low-k dielectric layer; forming a diffusion barrier layer in the opening, wherein the diffusion barrier layer has a top edge substantially level with a top surface of the low-k dielectric layer; filling a metal line in the opening; recessing a top surface of the metal line below a top edge of the diffusion barrier layer to form a recess; and forming a metal cap on the metal line, wherein the metal cap is substantially within the recess.

In accordance with another aspect of the present invention, a method of forming an integrated circuit includes providing a semiconductor substrate; forming a low-k dielectric layer over the semiconductor substrate; forming an opening extending from a top surface of the low-k dielectric layer into the low-k dielectric layer; forming a diffusion barrier layer in the opening; filling a copper-containing material into the opening; performing a chemical mechanical polish (CMP) to remove excess copper-containing material over the low-k dielectric layer, wherein the copper-containing material in the opening forms a copper line; selectively over-polishing the copper line to form a recess, so that a portion of the copper line adjoining the diffusion barrier layer has a top surface lower than a top edge of the diffusion barrier layer; and forming a metal cap on the copper line, wherein the metal cap is substantially within the recess.

In accordance with yet another aspect of the present invention, an integrated circuit includes a semiconductor substrate; a low-k dielectric layer over the semiconductor substrate; a first opening in the low-k dielectric layer; a first diffusion barrier layer in the first opening, wherein the first diffusion barrier layer covers the low-k dielectric layer in the first opening; a first metal line filling the first opening, wherein the first metal line has a top surface lower than a top edge of the first diffusion barrier layer, forming a recess; and a metal cap on the first metal line and substantially in the recess.

In accordance with yet another aspect of the present invention, an integrated circuit structure includes a semiconductor substrate; a low-k dielectric layer over the semiconductor substrate; a first copper line in the low-k dielectric layer, wherein the first copper line has a width of less than about 0.1 μm; and a first diffusion barrier layer between the first copper line and the low-k dielectric layer from sides and bottom. A first top surface of the first copper line is recessed from a top edge of the first diffusion barrier layer to form a first recess. The first recess has a depth of greater than about 50 Å. The integrated circuit structure further includes a first metal cap on the first copper line, wherein the first metal cap is substantially in the first recess; a second copper line in the low-k dielectric layer; and a second diffusion barrier layer between the second copper line and the low-k dielectric layer. A second top surface of the second copper line is recessed from a top edge of the second diffusion barrier layer to form a second recess. The second recess has a depth of less than about 200 Å. The integrated circuit structure further includes a second metal cap on the second copper line, wherein the second metal cap is substantially in the second recess.

The advantageous features of the present invention include improved coverage of metal cap layers, reduced topography, and increased lifetime of the respective interconnect structures.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional interconnect structure, wherein metal caps are formed on copper lines, and wherein the metal caps are above the corresponding low-k dielectric layer;

FIGS. 2 through 6B are cross-sectional views of intermediate stages in the manufacturing of an embodiment of the present invention;

FIG. 7 illustrates a dual damascene embodiment of the present invention; and

FIG. 8 illustrates cumulative failure rates of sample devices as functions of failure time.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

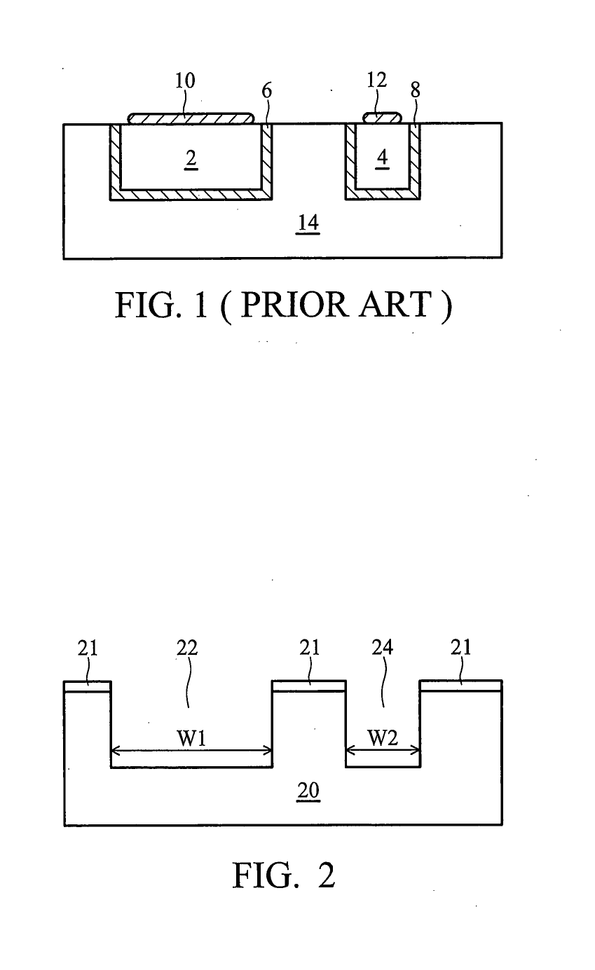

FIGS. 2 through 6B are cross-sectional views of intermediate stages in the making of an embodiment of the present invention. FIG. 2 illustrates the formation of trenches 22 and 24 in dielectric layer 20. In the preferred embodiment, dielectric layer 20 has a dielectric constant (k value) lower than about 3.5, and hence is alternatively referred to as low-k dielectric layer 20. Low-k dielectric layer 20 preferably contains nitrogen, carbon, hydrogen, oxygen, fluorine, and combinations thereof. The exemplary materials include un-doped silicate glass (USG), fluorinated silica glass (FSG), and the like. Furthermore, the k value of low-k dielectric layer 20 may be lower than about 2.5 (hence is referred to as an extremely low-k dielectric layer). In an exemplary embodiment, trench 22 is a wide trench with width W1 of greater than about 5 μm, while trench 24 is a narrow trench with width W2 of less than about 0.1 μm.

Optionally, dielectric layer 21, which acts as a chemical mechanical polish (CMP) stop layer, is formed on dielectric layer 20. Preferably, CMP stop layer 21 comprises a material selected from silicon nitride, silicon oxynitride, oxides, carbon-doped oxides, tetra-ethyl-ortho-silicate (TEOS), and combinations thereof. The preferred formation method is plasma enhanced chemical vapor deposition (PECVD). However, other commonly used methods such as high-density plasma CVD (HDPCVD), atomic layer CVD (ALCVD), and the like can also be used. In an exemplary embodiment wherein dielectric layer 21 comprises silicon nitride or silicon carbide, the formation is preferably performed in a chamber, in which gaseous precursors such as silane (SiH₄) and ammonia (NH₃) are introduced for a chemical reaction. For simplicity, CMP stop layer 21 is not shown in subsequent drawings.

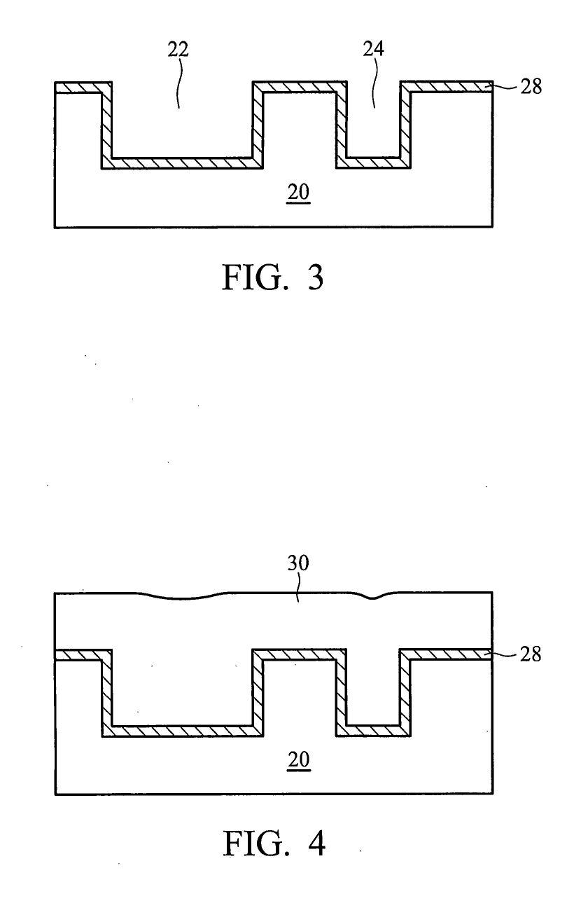

FIG. 3 illustrates the blanket formation of diffusion barrier layer 28, which covers the sidewalls and bottoms of trenches 22 and 24. Diffusion barrier layer 28 is preferably formed of a material including titanium, titanium nitride, tantalum, tantalum nitride, ruthenium, ruthenium nitride, and combinations thereof. The preferred formation methods include physical vapor deposition (PVD), atomic layer deposition (ALD), and other commonly used methods.

Referring to FIG. 4, a seed layer (not shown), which preferably includes copper or copper alloys, is formed on diffusion barrier layer 28. A metallic material 30 is then filled into trenches 22 and 24, preferably using plating. Metallic material 30 preferably includes copper or copper alloys, although other materials such as aluminum, tungsten, silver, and combinations thereof, can also be used.

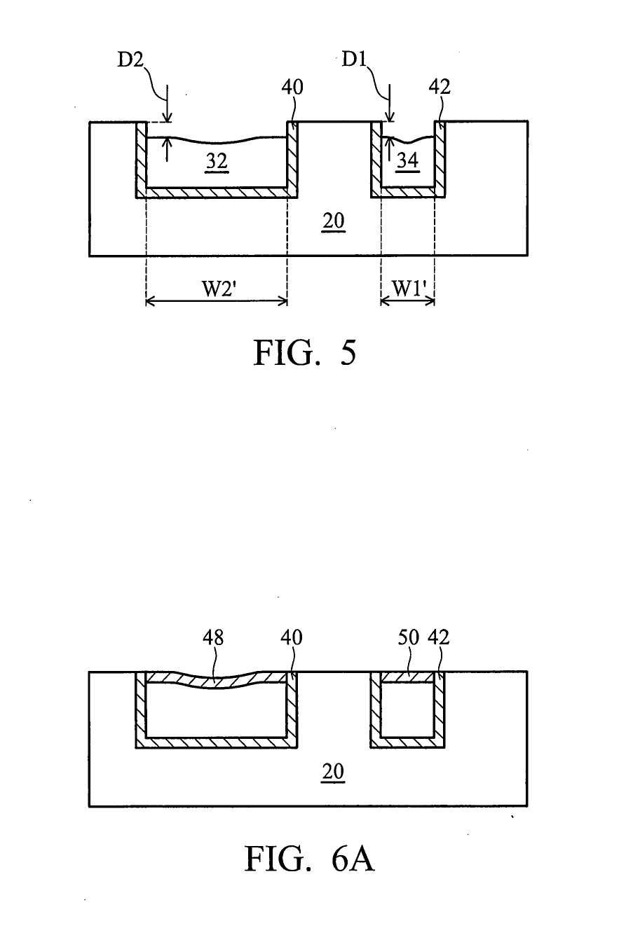

Referring to FIG. 5, a chemical mechanical polish (CMP) is performed to remove excess metallic material 30. In the case wherein CMP stop layer 21 (refer to FIG. 2) exists, the CMP stops at CMP stop layer 21. Otherwise, the CMP stops at low-k dielectric layer 20. As a result, diffusion barrier layers 40 and 42 and conductive lines 32 and 34 are formed. Throughout the description, conductive lines 32 and 34 are alternatively referred to as copper lines 32 and 34 although they may include other conductive materials.

In the preferred embodiment, the slurry used for the CMP includes CMP abrasives, slurry solvents, surfactants, chelating agents, pH buffers and stabilizer, corrosion inhibitors and selectivity tuning agents. In an exemplary embodiment, the CMP abrasives include particles of SiO₂, Al₂O₃ or CeO₂, polymer composites, and combinations thereof. The slurry solvents may include water and/or other organic solvents, inorganic solvents, and combinations thereof. The surfactants may include anionic, cationic & non-ion substances. The chelating agents may include organic and/or inorganic agents. The pH buffers and stabilizers may include H₃PO₄, NH₄OH, oxalic acid, citric acid, and combinations thereof. The corrosion inhibitors may include Benzotriazole (BTA), Triazole (TA), Quinoline Carboxylic Acid (QCA), and other organic inhibitors.

In the preferred embodiment, the selective tuning agents include H₂O₂, which oxidizes and thus softens copper, and low-k inhibitors for preventing low-k dielectric layer 20 from being polished. In addition, organic additives such as ethylenediamine, glycolic acid, ethylenediaminetetraacetic acid, oxalic acid, and the like are included. Throughout the description, the organic additives are also referred to as dishing promoters as they are used to increase the dishing effects in copper lines 32 and 34. Preferably, the ratio of H₂O₂ to the dishing promoters is adjusted so that dishing effects throughout a wafer are substantially uniform. In addition, the ratio is adjusted so that the pattern-loading effects are reduced, and the dishing depth difference between wide copper lines and narrow copper lines is reduced. In an exemplary embodiment wherein the dishing promoters include phosphoric acid, nitric acid, acetic acid, a weight ratio of H₂O₂ to the dishing promoters is preferably between about 0.01% and about 1.0%. The use of the dishing promoters also means that in the CMP process, chemical reaction is relied upon more than if the dishing promoters were not used. Advantageously, this results in lesser force being applied on low-k dielectric layer 20 during the CMP. As a result, the low-k dielectric peeling, particularly at the interface of low-k dielectric layer and underlying metal cap (not shown), if any, will be significantly reduced.

Preferably, over-polishing is performed after the portion of metallic material 30 over low-k dielectric layer 20 has been removed, resulting in increased dishing effects in copper lines 32 and 34, and hence recesses 44 and 46 are formed. Preferably, depth D1 and D2, which are measured where copper lines 32 and 34 join the respective diffusion barriers 40 and 42, are preferably greater than about 30 Å, and more preferably between about 30 Å and about 100 Å. It is realized that, naturally, center portions of copper lines 32 and 34 are likely to be recessed more than the edge portions of copper line 32 and 34, respectively.

Advantageously, by using the above-discussed slurry, the dishing effects are more uniform throughout the wafer. For example, for a narrow copper line 34 having a width W1′ of less than about 0.1 μm, recess depth D1 is greater than about 50 Å, while for a wide copper line 32 having a width W2′ of greater than about 5 μm, recess depth D2 is less than about 200 Å. This is significantly improved over the conventional CMP process, wherein if a narrow copper line with a width of less than about 0.1 μm has a recess depth of about 50 Å, wide copper lines with widths of greater than about 5 μm would have recess depths of about 300 Å to about 500 Å.

In alternative embodiments, after the CMP process, the top surfaces of copper lines 32 and 34 are etched to form the desired recesses 44 and 46. In this embodiment, the etching may use chemicals that are typically used for post-CMP cleaning, such as HF. Other chemicals such as amino acids, (NH₄)₂S₂O₈, and like can also be used. The etching process may be combined with the CMP process, in which the CMP process creates recesses, and the etching increases the depth of recesses 44 and 46 to desired levels.

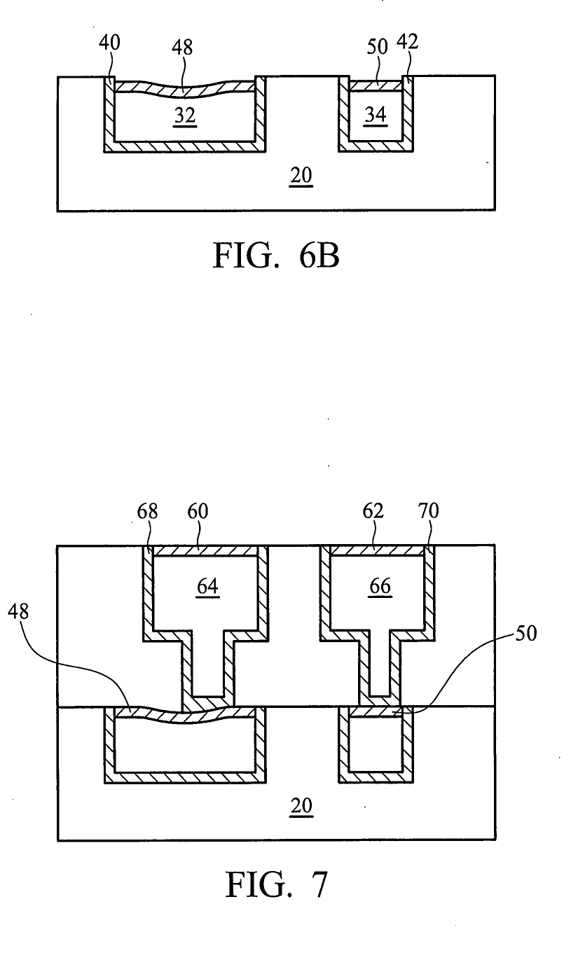

FIG. 6A illustrates the formation of metal caps 48 and 50 on copper lines 32 and 34, respectively. Metal caps 48 and 50 preferably comprise materials such as CoP, CoB, CoWP, CoWB, NiWP, CoSnP, NiWB, CuSi, ZrN, NiMoP, and combinations thereof. Metal caps 48 and 50 may also be composite layers including more than one layer, wherein each of the layers includes one or more of the above-discussed materials. In the preferred embodiment, metal caps 48 and 50 are formed by electroless plating and are selectively formed only on exposed surfaces of copper lines 32 and 34, respectively, but not on top edges of diffusion barrier layers 40 and 42 and the top surface of dielectric layer 20. The selective formation of metal caps 48 and 50 may be achieved by using a non-palladium catalyst, enabling direct electroless plating. In other embodiments, metal caps 48 and 50 can be formed by depositing a metal cap layer using commonly techniques such as PVD, sputtering and ALD, and then etching the metal cap layer to form metal caps 48 and 50.

The preferred thickness of metal caps 48 and 50 is between about 10 Å and about 200 Å, and more preferably between about 50 Å and about 100 Å. In the preferred embodiment, the top surfaces of the resulting metal caps 48 and 50 are either level with the top edges of diffusion barrier layers 40 and 42, as is shown in FIG. 6A, or lower than the top edges of diffusion barrier layers 40 and 42, as is shown in FIG. 6B.

In the embodiments provided in the preceding paragraphs, a single damascene process is discussed to explain the concepts of the present invention. One skilled in the art will realize that the teaching is readily available for dual damascene processes. FIG. 7 illustrates an interconnect structure including dual damascene structures. Similarly, in this embodiment, metal caps 60 and 62 are preferably formed only on respective copper lines 64 and 66, but not on the respective diffusion barrier layers 68 and 70. Metal caps 60 and 62 may be formed using essentially the same method as forming metal caps 48 and 50. One skilled in the art will realize the corresponding formation steps.

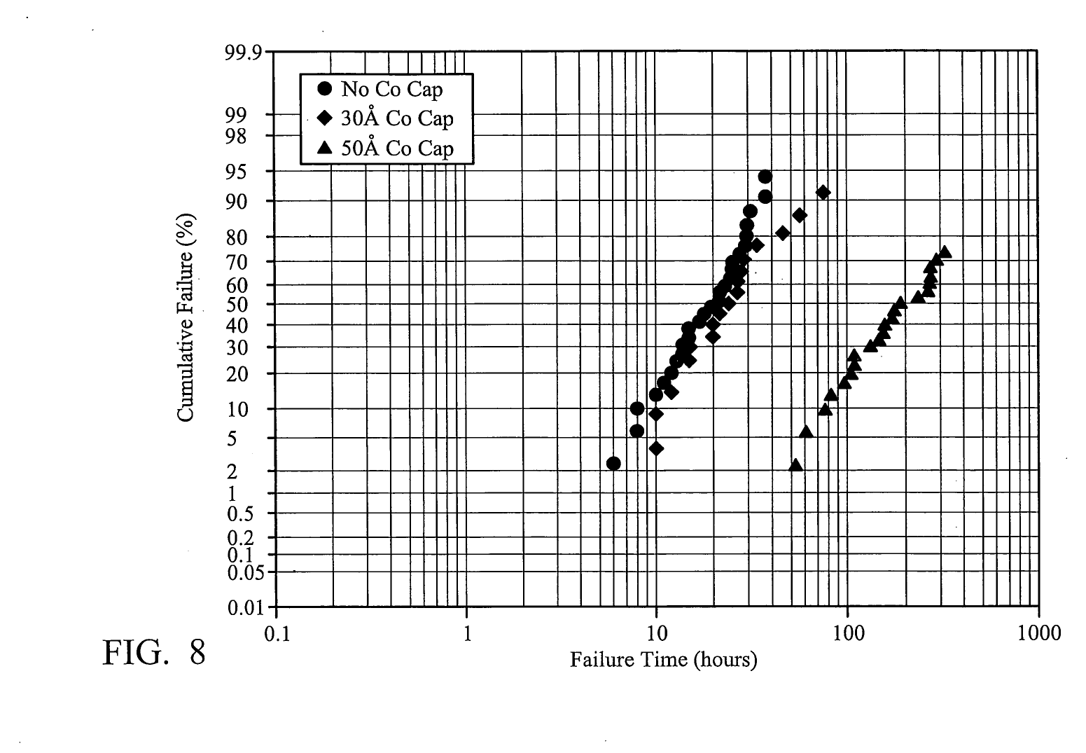

The embodiments of the present invention have several advantageous features. First, metal caps can be more uniformly formed on copper lines with substantially no gaps between the metal caps and the respective diffusion barrier layers. Accordingly, the mean-time-to-failure (MTTF) of the interconnect structure is improved by greater than about two times, and even as high as ten times. An experiment's results have been shown in FIG. 8, in which the failures times of three groups of metal line samples are compared. FIG. 8 illustrates cumulative failure rates of samples as functions of failure time. It is noted that metal caps help improve the failure time of metal line samples. Further, the failure time of metal line samples with 50 Å cobalt caps is about 10 times longer than the failure time of metal line samples with no metal caps, and metal line samples with 30 Å cobalt caps. Experiment results have also shown one hundred percent yield in tested samples as to the line-to-line leakages, via chain contact resistances and metal line sheet resistances. With the use of the novel slurry, the topography of the resulting structure is reduced. A further advantageous feature is that the above-discussed improvement can be obtained without the cost of additional process steps and masks.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming an integrated circuit structure, the method comprising:
providing a semiconductor substrate;
forming a low-k dielectric layer over the semiconductor substrate;
forming an opening extending from a top surface of the low-k dielectric layer into the low-k dielectric layer;
forming a diffusion barrier layer in the opening, wherein the diffusion barrier layer has a top edge substantially level with a top surface of the low-k dielectric layer;
filling a metal line in the opening;
recessing a top surface of the metal line below a top edge of the diffusion barrier layer to form a recess; and
forming a metal cap on the metal line, wherein the metal cap is substantially within the recess.

2. The method of claim 1, wherein the metal cap has a top surface level with or lower than the top edge of the diffusion barrier layer.

3. The method of claim 2, wherein the steps of filling the metal line and recessing the top surface of the metal line comprises:
filling a metallic material into the opening;
performing a chemical mechanical polish (CMP) to remove excess metallic material over the low-k dielectric layer; and
over-polishing the metal line to form the recess.

4. The method of claim 3, wherein the CMP is performed using a slurry comprising H₂O₂ and an organic dishing promoter.

5. The method of claim 4 further comprising adjusting a ratio of the H₂O₂ and the organic dishing promoter to reduce a dishing difference between wide metal lines and narrow metal lines.

6. The method of claim 4, wherein the organic dishing promoter is selected from the group consisting essentially of ethylenediamine, glycolic acid, ethylenediaminetetraacetic acid, oxalic acid, and combinations thereof.

7. The method of claim 3, wherein after the step of over-polishing, a narrow metal line with a width of less than about 0.1 μm has a recess depth of greater than about 50 Å, and a wide copper line with a width of greater than about 5 μm has a recess depth of less than about 200 Å.

8. The method of claim 1, wherein the step of recessing the top surface of the metal line comprises etching the metal line.

9. The method of claim 1, wherein the step of forming the metal cap comprises electroless plating.

10. A method of forming an integrated circuit structure, the method comprising:
providing a semiconductor substrate;
forming a low-k dielectric layer over the semiconductor substrate;
forming an opening extending from a top surface of the low-k dielectric layer into the low-k dielectric layer;
forming a diffusion barrier layer in the opening;
filling a copper-containing material into the opening;
performing a chemical mechanical polish (CMP) to remove excess copper-containing material over the low-k dielectric layer, wherein the copper-containing material in the opening forms a copper line;
selectively over-polishing the copper line to form a recess, so that a portion of the copper line adjoining the diffusion barrier layer has a top surface lower than a top edge of the diffusion barrier layer; and
forming a metal cap on the copper line, wherein the metal cap is substantially within the recess.

11. The method of claim 10, wherein the CMP is performed using a slurry comprising H₂O₂ and an organic dishing promoter, and wherein the organic dishing promoter is selected from the group consisting essentially of ethylenediamine, glycolic acid, ethylenediaminetetraacetic acid, oxalic acid, and combinations thereof.

12. The method of claim 11 further comprising adjusting a weight ratio of H₂O₂ to the organic dishing promoter to reduce a dishing depth difference between a wide copper line and a narrow copper line.

13. The method of claim 12, wherein the organic dishing promoter comprises ethylenediaminetetraacetic, and wherein a weight ratio of H₂O₂ to ethylenediaminetetraacetic is between about 0.01% and about 1.0%.

14. The method of claim 10, wherein after the step of selective over-polishing, a narrow copper line with a width of less than about 0.1 μm has a recess depth of greater than about 50 Å, and a wide copper line with a width of greater than about 5 μm has a recess depth of less than about 200 Å.

15. The method of claim 10, wherein the step of forming the metal cap comprises electroless plating, and wherein the metal cap is only selectively formed on the copper line.

16. An integrated circuit structure comprising:
a semiconductor substrate;
a low-k dielectric layer over the semiconductor substrate;
a first opening in the low-k dielectric layer;
a first diffusion barrier layer in the first opening, wherein the first diffusion barrier layer covers the low-k dielectric layer in the first opening;
a first metal line filling the first opening, wherein the first metal line has a top surface lower than a top edge of the first diffusion barrier layer, forming a recess; and
a metal cap on the first metal line and substantially in the recess.

17. The integrated circuit structure of claim 16, wherein the metal line comprises copper.

18. The integrated circuit structure of claim 16, wherein a top surface of the metal cap is substantially level with or lower than the top edge of the first diffusion barrier layer.

19. The integrated circuit structure of claim 16, wherein the first metal line has a width of less than about 0.1 μm, and a recess depth of greater than about 50 Å, and wherein the integrated circuit further comprises:
a second metal line in the low-k dielectric layer, wherein the second metal line has a width of greater than about 5 μm; and
a recess in the second metal line with a recess depth of less than about 200 Å.

20. The integrated circuit structure of claim 16, wherein the recess of the first metal line is greater than about 30 Å.

21. The integrated circuit structure of claim 16, wherein the metal cap has a top surface substantially level with or lower than the top edge of the first diffusion barrier layer.

22. An integrated circuit structure comprising:
a semiconductor substrate;
a low-k dielectric layer over the semiconductor substrate;
a first copper line in the low-k dielectric layer, wherein the first copper line has a width of less than about 0.1 μm;
a first diffusion barrier layer between the first copper line and the low-k dielectric layer from sides and bottom, wherein a first top surface of the first copper line is recessed from a top edge of the first diffusion barrier layer to form a first recess, and wherein the first recess has a depth of greater than about 50 Å;
a first metal cap on the first copper line, wherein the first metal cap is substantially in the first recess;
a second copper line in the low-k dielectric layer;
a second diffusion barrier layer between the second copper line and the low-k dielectric layer, wherein a second top surface of the second copper line is recessed from a top edge of the second diffusion barrier layer to form a second recess, and wherein the second recess has a depth of less than about 200 Å; and
a second metal cap on the second copper line, wherein the second metal cap is substantially in the second recess.

23. The integrated circuit structure of claim 22, wherein each of the first and the second top surfaces are substantially level with or lower than the respective first and the second top edges of the respective first and second barrier layers.

24. The integrated circuit structure of claim 22, wherein the first and the second metal caps comprises a material selected from the group consisting essentially of CoP, CoB, CoWP, CoWB, NiWP, CoSnP, NiWB, CuSi, ZrN, NiMoP, and combinations thereof.
